(19) United States
(12) Patent Application Publication
(10) Pub. No.: US 2024/0364275 A1
(43) Pub. Date: Oct. 31, 2024

(54) RF CIRCUIT SUPPORTING PREDISTORTION AND METHOD OF OPERATING THE SAME

(71) Applicant: SAMSUNG ELECTRONICS CO., LTD., Suwon-si (KR)

(72) Inventors: Kyungwoo YOO, Suwon-si (KR); Hongmin CHOI, Suwon-si (KR); Sanghyun BAEK, Suwon-si (KR); Hyung Sun LIM, Suwon-si (KR)

(73) Assignee: SAMSUNG ELECTRONICS CO., LTD., Suwon-si (KR)

(21) Appl. No.: 18/606,982

(22) Filed: Mar. 15, 2024

(30) Foreign Application Priority Data
Apr. 25, 2023 (KR) 10-2023-0054359
Jul. 3, 2023 (KR) 10-2023-0085924

(51) Int. Cl. H03F 1/32; H03F 3/24; H04B 1/04

(52) U.S. Cl. CPC H03F 1/3241; H03F 3/245; H04B 1/0475; H03F 2200/451; H04B 2001/0425

(57) ABSTRACT

A radio-frequency (RF) circuit is provided. The RF circuit includes: a power amplifier; a predistortion circuit configured to predistort an input signal based on reference predistortion information to obtain a predistortion signal, and output the predistortion signal to the power amplifier; and a gain circuit configured to provide a gain, corresponding to a reciprocal of a nonlinear coefficient of the power amplifier, to the predistortion circuit.

### CROSS-REFERENCE TO RELATED APPLICATIONS

This application claims priority to Korean Patent Application Nos. 10-2023-0054359, filed on Apr. 25, 2023, and 10-2023-0085924, filed on Jul. 3, 2023, in the Korean Intellectual Property Office, the disclosures of which are incorporated by reference herein in their entireties.

### BACKGROUND

One or more example embodiments relate to a radio-frequency (RF) circuit supporting predistortion and a method of operating the same.

A power amplifier has nonlinear characteristics in which nonlinearity is present between an input signal and an output signal. A predistortion (PD) scheme (or a digital PD scheme) is used to compensate for the nonlinearity of the power amplifier in a digital domain.

The nonlinearity of the power amplifier may vary depending on various environmental factors (for example, carrier frequency, temperature, magnitude of an output signal, or the like). For example, when carrier frequencies are different from each other, different nonlinear amplitude modulation (AM) and AM graphs may be identified. Different predistortion schemes may be implemented for different environmental factors to compensate for different nonlinearities.

### SUMMARY

One or more example embodiments provide a radio-frequency (RF) circuit, supporting predistortion in spite of nonlinear variation caused by a change in environment, and a method of operating the same.

According to an aspect of an example embodiment, a radio-frequency (RF) circuit includes: a power amplifier; a predistortion circuit configured to predistort an input signal based on reference predistortion information to obtain a predistortion signal, and output the predistortion signal to the power amplifier; and a gain circuit configured to provide a gain, corresponding to a reciprocal of a nonlinear coefficient of the power amplifier, to the predistortion circuit.

According to an aspect of an example embodiment, a method of operating a radio-frequency (RF) circuit includes: setting an index m of reference predistortion information, wherein m is a positive integer; obtaining m-th reference predistortion information and an m-th reference model corresponding to the index m as a reference model, the reference model corresponding to a power amplifier; identifying a gain corresponding to a reciprocal a nonlinear coefficient for the m-th reference predistortion information and the power amplifier; and predistorting an input signal based on the gain.

According to an aspect of an example embodiment, a wireless communication device includes: a modem configured to process a baseband signal; a radio-frequency integrated circuit (RFIC) configured to convert the baseband signal into a radio-frequency (RF) signal; a power amplifier configured to amplify the RF signal; and an antenna configured to transmit and receive the RF signal. The modem includes: a predistortion circuit configured to predistort the baseband signal based on predistortion information; and a gain circuit configured to provide a gain, corresponding to a reciprocal of a nonlinear coefficient of the power amplifier, to the predistortion circuit.

### BRIEF DESCRIPTION OF DRAWINGS

The above and other aspects, features, and advantages of the present disclosure will be more clearly understood from the following description, taken in conjunction with the accompanying drawings.

FIG. 1 is a diagram illustrating a radio-frequency (RF) circuit according to an example embodiment.

FIG. 2 is a diagram illustrating a nonlinearity compensation operation of predistortion circuit.

FIGS. 3 to 5 are diagrams illustrating a predistortion operation of an RF circuit according to an example embodiment.

FIG. 6 is a diagram illustrating an RF circuit according to an example embodiment.

FIG. 7 is a diagram illustrating an operation of a predistortion circuit according to an example embodiment.

FIG. 8 is a diagram illustrating an RF circuit according to an example embodiment.

FIG. 9 is a flowchart illustrating a method of operating an RF circuit according to an example embodiment.

FIG. 10 is a flowchart illustrating a method of operating an RF circuit according to an example embodiment.

FIG. 11 is a diagram illustrating a wireless communication device according to an example embodiment.

### DETAILED DESCRIPTION

Hereinafter, example embodiments will be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present.

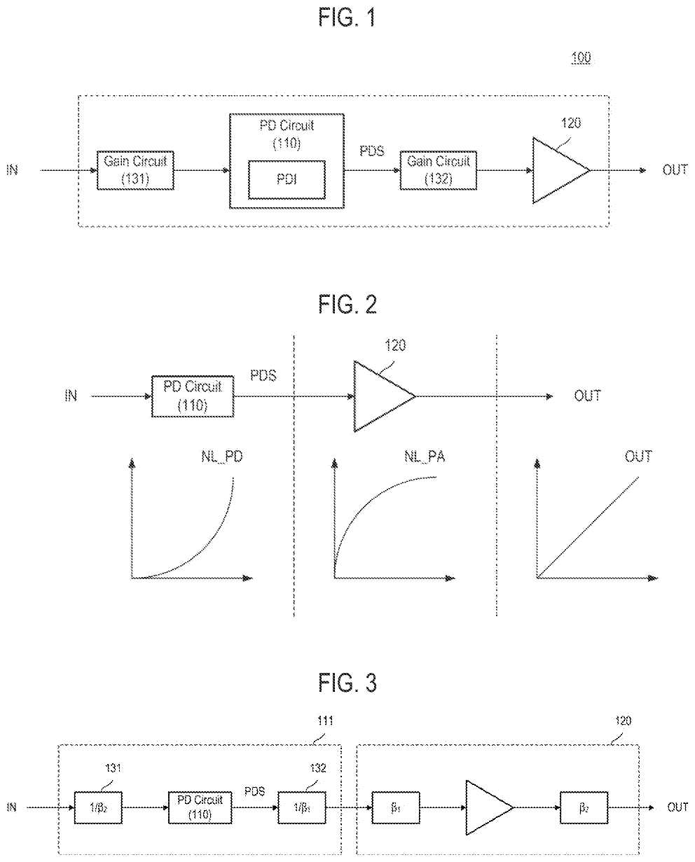

FIG. 1 is a diagram illustrating a radio-frequency (RF) circuit according to an example embodiment.

Referring to FIG. 1, an RF circuit 100 according to an example embodiment may include a predistortion circuit 110, a power amplifier 120, and gain circuits 131 and 132.

The predistortion circuit 110 may be provided at an input terminal of the power amplifier 120, and may be configured to predistort an input signal IN based on reference predistortion information PDI and to output a predistortion signal PDS for the input signal IN to the power amplifier 120. A predistortion operation of the predistortion circuit 110 may refer to a technique to distort (i.e., predistort) the input signal IN based on nonlinearity inverse to the nonlinear characteristics of the power amplifier 120. The predistortion may allow nonlinearity of the power amplifier 120 to be compensated for.

For example, the input signal IN of the predistortion circuit 110 may be a digital signal in a baseband. Accordingly, the predistortion operation of the predistortion circuit 110 may be understood as being performed in the digital domain. The input signal IN may be, for example, an original signal to be amplified by the power amplifier 120 or a desired output signal, a target output signal OUT. When the desired output signal is the input signal IN, a power level of the desired output signal may be similar to a power level of the output signal OUT, so that a gain division block for normalization may be omitted at the output terminal of the power amplifier 120. Alternatively, when the input signal IN is the original signal, a gain division block for normalization may be added to the output terminal of the power amplifier 120, for example, a feedback loop. The gain division block may perform an operation of dividing the output signal OUT by a gain GO of the linearized power amplifier 120.

Hereinafter, a case in which the input signal IN is a desired output signal will be provided for ease of description, but example embodiments are not limited thereto.

Reference predistortion information PDI used for predistortion may be defined as information, used to predistort a signal provided to a power amplifier 120, with respect to the power amplifier 120 having nonlinearity in a reference scenario (or environment). The reference scenario is not particularly limited, and may correspond to an arbitrary scenario (or environment). Environmental factors such as carrier frequency, temperature, and magnitude of the output signal OUT of the RF circuit 100 may affect operation of the power amplifier 120 and may also vary under different scenarios, so that the power amplifier 120 may have different nonlinearities under the different scenarios.

For example, with respect to a k-th scenario (where k is a positive integer), predistortion information for predistorting nonlinearity under the k-th scenario may be defined as reference predistortion information PDI. Accordingly, the nonlinearity of the power amplifier 120 varies depending on the scenario, so that the reference predistortion information PDI may be maintained as it is or may no longer be used.

For example, the predistortion information may include a predistortion look-up table (LUT) for distortion compensation and a predistortion coefficient. In this case, the predistortion LUT may include at least one of an AM/AM LUT and an AM/PM LUT. Accordingly, the reference predistortion information PDI may be defined as including a predistortion LUTs and a predistortion coefficient configured to predistort nonlinearity in a reference scenario as a reference.

The power amplifier 120 may be connected to an output terminal of the predistortion circuit 110 and may amplify power of the predistortion signal PDS, an output signal OUT of the predistortion circuit 110, to generate an output signal OUT. For example, the power amplifier 120 may have a gain G, where G is a real number. Because the power amplifier 120 has nonlinear characteristics as described above, the output signal OUT may be distorted when a nonlinearity compensation operation such as a predistortion operation is absent. Nonlinearity of the output signal OUT may be eliminated by the above-described predistortion circuit 110.

When the scenario is changed, for example when environmental factors charge, nonlinearity of the power amplifier 120 in the changed scenario may be different than in the reference scenario. As discussed below, a model of the power amplifier 120 in the reference scenario will be defined as a reference model 112. A coefficient used to define the nonlinearity of the reference model 112 will be referred to as a nonlinear coefficient.

The gain circuits 131 and 132 may be configured to provide a gain, defined as a reciprocal of a nonlinear coefficient for the above-described power amplifier 120, to an input/output terminal of the predistortion circuit 110. For example, when the nonlinearity of the power amplifier 120 is changed, the gain circuits 131 and 132 may be configured to inversely compensate for a nonlinear coefficient corresponding to the changed nonlinearity. When the scenario is changed, the gain circuits 131 and 132 provided at the input/output terminals of the predistortion circuit 110 may adjust the gain to be provided to the input/output terminals of the predistortion circuit 110 as a reciprocal of the changed nonlinear coefficient, and may then provide the adjusted gain to the predistortion circuit 110.

In this case, when the scenario is changed, the predistortion circuit 110 may continue to compensate for nonlinearity while maintaining the reference predistortion information PDI, and does not need to compensate for nonlinearity using different predistortion information PDI for each changed scenario.

Accordingly, the RF circuit 100 may continue to compensate for nonlinearity using the reference predistortion information PDI even in a changed scenario and may only provide a gain, defined as the reciprocal of the nonlinear coefficient, to compensate for nonlinearity in the changed scenario. When the predistortion information PDI is stored for each changed scenario, there may be issues regarding resource allocation of the predistortion operation, time required to extract information, and a storage space of the electronic device including the RF circuit 100. In example embodiments, reference predistortion information PDI may be used as it is, so that the issues regarding the resource allocation, the required time, and the storage space may be addressed. In addition, the RF circuit 100 according to example embodiments may obtain desired output power of the power amplifier 120 while performing a predistortion operation.

FIG. 2 is a diagram illustrating a nonlinearity compensation operation of a predistortion circuit.

Referring to FIG. 2, the power amplifier 120 has nonlinear characteristics caused by a nonlinear element, or the like, as described above. Thus, the power amplifier 120 may have nonlinear distortion NL_PA causing an output signal OUT to be distorted. The predistortion circuit 110 may be connected to an input terminal of the power amplifier 120 to compensate for such nonlinearity, and may be designed to have distortion NL_PD, inverse to the nonlinear distortion NL_PA of the power amplifier 120, based on reference predistortion information PDI.

Accordingly, even when an output signal OUT of the power amplifier 120 is amplified through a power amplifier 120 having nonlinear distortion NL_PA, the input signal IN has already been converted by the PD circuit 110 into a signal having inverse distortion NL_PD to compensate for nonlinear characteristics of the power amplifier 120. Thus, the output signal OUT of the power amplifier 120 may have the linear characteristics. In addition, when the nonlinear characteristics are compensated for through the predistortion circuit 110, an adjacent channel leakage ratio (ACLR) may be reduced. Thus, current consumption of the power amplifier 120 may be reduced, and an error vector magnitude (EVM) may also be reduced.

In an example embodiment, an output of the predistortion circuit 110 performing the above-described predistortion operation, for example, a predistortion signal PDS may be defined as f_{DPD}(x)=Xα, where f_{DPD} is a function of the predistortion circuit 110, and X and α may be expressed by a memory polynomial (MP) model, a type of Volterra series used to model a nonlinear system. As an example, X may be defined as a vector in which an input signal IN is expressed based on the number of taps of a memory 150 of the MP model and a polynomial order, and a may be defined as a predistortion coefficient or a vector having a predistortion coefficient as an element.

FIGS. 3 to 5 are diagrams illustrating a predistortion operation of an RF circuit according to an example embodiment.

Referring to FIG. 3, when the power amplifier 120 included in the RF circuit 100 according to an example embodiment operates under a changed scenario, nonlinearity changed depending on a change in scenario may be modeled as a nonlinear coefficient. For example, a nonlinear coefficient may include a first nonlinear coefficient β₁, corresponding to an input terminal of the power amplifier 120, and a second nonlinear coefficient β₂ corresponding to an output terminal of the power amplifier 120. The first nonlinear coefficient β₁ and the second nonlinear coefficient β₂ may be positive real numbers.

The gain circuit 111 may be connected to input and output terminals of the predistortion circuit 110. In an example embodiment, the gain circuit 111 may include a first gain circuit 131 and a second gain circuit 132, as illustrated in FIG. 3. The first gain circuit 131 may be configured to provide a first gain, defined as a reciprocal of the second nonlinear coefficient β₂, to an input terminal of the predistortion circuit 110. The second gain circuit 132 may be configured to provide a second gain, defined as a reciprocal of the first nonlinear coefficient β₁, to an output terminal of the predistortion circuit 110. Accordingly, the first gain circuit 131 may be configured to output the input signal IN, multiplied by the first gain, to the predistortion circuit 110, and the second gain circuit 132 may be configured to output a predistortion signal PDS, multiplied by the second gain, to the power amplifier 120.

In this case, an input signal IN applied to the input terminal of the predistortion circuit 110 may be compensated for by the first gain, and the predistortion signal PDS output from the output terminal of the predistortion circuit 110 may be compensated for by the second gain.

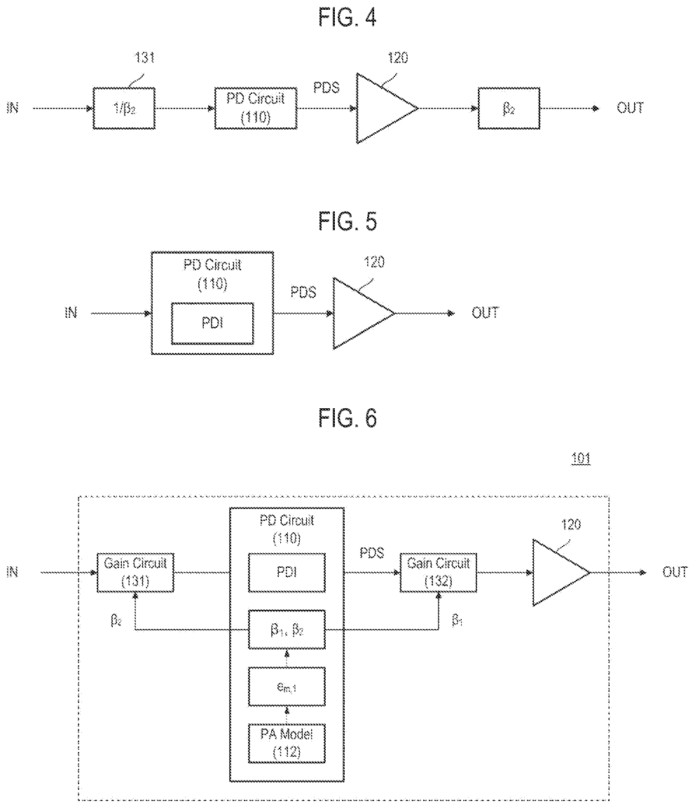

Referring to FIG. 4, the first nonlinear coefficient β₁ may be compensated for by the second gain provided from the second gain circuit 132. For example, the first nonlinear coefficient β₁ corresponding to the input terminal of the power amplifier 120 may be compensated for when a predistortion signal PDS multiplied by the second gain is applied to the power amplifier 120.

Referring to FIG. 5, the second nonlinear coefficient β₂ may be compensated for by the first gain provided from the first gain circuit 131. For example, the second nonlinear coefficient β₂ corresponding to the output terminal of the power amplifier 120 may be compensated for through the first gain multiplied by the input signal IN. Ultimately, the predistortion circuit 110 may compensate for nonlinearity in a changed scenario using only reference predistortion information PDI.

FIG. 6 is a diagram illustrating an RF circuit according to an example embodiment.

Referring to FIG. 6, the predistortion circuit 110 included in the RF circuit 101 according to an example embodiment may perform a predistortion operation and a nonlinear coefficient estimation operation based on reference predistortion information PDI.

In an example embodiment, the predistortion circuit 110 may obtain reference predistortion information PDI. For example, the predistortion circuit 110 may be expressed as an MP model, and the predistortion circuit 110 may control the MP model to obtain predistortion coefficients of the MP model as the reference predistortion information PDI.

In an example embodiment, the predistortion circuit 110 may model the power amplifier 120. For example, the power amplifier 120 may be expressed as an MP model or a memoryless polynomial model, and the predistortion circuit 110 may model the MP model or the memoryless polynomial model to obtain a reference model 112 of the power amplifier 120.

The above-described operations of obtaining the reference predistortion information PDI and the reference model 112 may be performed by the predistortion circuit 110 under a reference scenario. For example, the obtained reference model 112 may be defined as f_{PA}(β₁x) (where β₁ is a first nonlinear coefficient and x is an input signal of the power amplifier 120 (for example, the predistortion signal PDS)).

In an example embodiment, the predistortion circuit 110 may estimate a nonlinear coefficient based on significant reduction of a first error e_{m,1} defined based on a reference model 112 modeled from the power amplifier 120, a first output signal OUT that is an actual signal output from the power amplifier 120, and a nonlinear coefficient. For example, the first error e_{m,1} may be defined as a normalized mean square error (NMSE) between a first output signal OUT and a second output signal that is an output when the first nonlinear coefficient β₁ and the second nonlinear coefficient β₂ are applied to the reference model 112. For example, the first error e_{m,1} may be defined by Equation 1 below.

$$J ( {β}_{1} , {β}_{2} ) = {‖ {\underline{y}}^{′} - {β}_{2} {\underline{f}}_{\underline{P} A} ( {β}_{1} \underline{x} ) ‖}_{2}^{2} , \qquad Equation 1$$

where J(β₁,β₂) may be defined a first error e_{m,1}, y′ may be defined as a first output signal OUT, and β₂f_{PA}(β₁x) may be defined as a second output signal. As described above, β₂ is a second nonlinear coefficient. For example, the first error e_{m,1} may be defined as a norm (for example, a Euclidean norm) of a difference vector between the first output signal OUT and the second output signal. Accordingly, the first error e_{m,1} may have a nonlinear relationship to the nonlinear coefficients.

When a nonlinear coefficient to be estimated is \hat{β}₁,\hat{β}₂, the nonlinear coefficient \hat{β}₁,\hat{β}₂ may be defined by Equation 2 below.

$${\hat{β}}_{1} , {\hat{β}}_{2} = arg {min}_{{β}_{1} , {β}_{2}} J ( {β}_{1} , {β}_{2} ) \qquad Equation 2$$

When Equation 2 is more generalized as a transposed matrix of \hat{β}₁,\hat{β}₂, it may be expressed as Equation 3 below.

$$\underline{\hat{β}} = arg {min}_{\underline{β}} J ( \underline{β} ) , \underline{β} {=}^{Δ} {[ {β}_{1} , {β}_{2} ]}^{T} , \qquad Equation 3$$

where [ ]^{T} denotes a transposition matrix.

For example, estimating \hat{β}₁,\hat{β}₂ is equal to finding a first nonlinear coefficient β₁ and a second nonlinear coefficient β₂ significantly reducing the first error e_{m,1}. Accordingly, the predistortion circuit 110 may estimate \hat{β}₁,\hat{β}₂ satisfying Equation 2, for example, \hat{β}₁,\hat{β}₂ significantly reducing the first error e_{m,1}. For example, the first error e_{m,1} may be identified as being significantly reduced when the first error e_{m,1} is less than a threshold value. As another example, the first error e_{m,1} may be identified as being significantly reduced when the first error e_{m,1} is less than other combinations of the first nonlinear coefficient β₁ and the second nonlinear coefficient β₂.

The predistortion circuit 110 may estimate a nonlinear coefficient, satisfying Equation 2 or Equation 3, based on various example embodiments.

In an example embodiment, the predistortion circuit 110 may estimate a nonlinear coefficient based on a linearization technique. For example, when g(β) [symbol] β₂f_{PA}(β₁x), J(β₁,β₂), the first error e_{m,1}, may be defined for the more generalized nonlinear coefficient β by Equation 4 below.

$$J ( \underline{β} ) = {( {\underline{y}}^{′} - {β}_{2} {\underline{f}}_{\underline{P} A} ( {β}_{1} \underline{x} ) )}^{H} ( {\underline{y}}^{′} - {β}_{2} {\underline{f}}_{\underline{P} A} ( {β}_{1} \underline{x} ) ) = {( {\underline{y}}^{′} - \underline{g} ( β ) )}^{H} ( {\underline{y}}^{′} - \underline{g} ( β ) ) , \qquad Equation 4$$

where ( )^{H} denotes a Hermitian matrix.

In Equation 4, g(β) may be approximated for βᵢₙᵢ, an initial value of β, by

Equation 5 below.

$$\underline{g} ( \underline{β} ) ≃ \underline{g} ( \underline{β} ) {\vert}_{\underline{β} = {\underline{β}}_{ini}} + \frac{\partial \underline{g} ( \underline{β} )}{\partial {\underline{β}}^{T}} {\vert}_{\underline{β} = {\underline{β}}_{ini}} ( \underline{β} - {\underline{β}}_{ini} ) = \underline{g} ( {\underline{β}}_{ini} ) + {\underline{G}}_{ini} ( \underline{β} - {\underline{β}}_{ini} ) , \qquad Equation 5$$

$$where \underline{g} ( {\underline{β}}_{ini} ) {=}^{Δ} \underline{g} ( \underline{β} ) {\vert}_{\underline{β} = {\underline{β}}_{ini}} , and {\underline{G}}_{ini} {=}^{Δ} \frac{\partial \underline{g} ( \underline{β} )}{\partial {\underline{β}}^{T}} {\vert}_{\underline{β} = {\underline{β}}_{ini}} .$$

Therefore, by substituting Equation 5 into Equation 4, J(β) may be defined by Equation 6 below.

$$J ( \underline{β} ) ≃ {( {\underline{y}}^{′} - \underline{g} ( {\underline{β}}_{ini} ) + {\underline{G}}_{ini} ( \underline{β} - {\underline{β}}_{ini} ) )}^{H} ( {\underline{y}}^{′} - \underline{g} ( {\underline{β}}_{ini} ) + {\underline{G}}_{ini} ( \underline{β} - {\underline{β}}_{ini} ) ) = {( \underline{z} + {\underline{G}}_{ini} Δ \underline{β} )}^{H} ( \underline{z} + {\underline{G}}_{ini} Δ \underline{β} ) , \qquad Equation 6$$

where z [symbol] y′−g(βᵢₙᵢ), and Δβ [symbol] β−βᵢₙᵢ. Therefore, an updated value Δ\hat{β} of the nonlinear coefficient for significantly reducing each term in Equation 6 may be defined by Equation 7 below.

$$Δ \underline{\hat{β}} = - {( {\underline{G}}_{ini}^{H} {\underline{G}}_{ini} )}^{- 1} {\underline{G}}_{ini}^{H} \underline{z} \qquad Equation 7$$

Accordingly, the predistortion circuit 110 may estimate, \hat{β}, a nonlinear coefficient satisfying Equation 3, based on Equation 8 defined by the initial value βᵢₙᵢ, the updated value Δ\hat{β} of the nonlinear coefficient defined by Equation 7, and weight information μ of the update value (where 0<μ<1).

$$\underline{\hat{β}} = {\underline{β}}_{ini} + μ Δ \underline{\hat{β}} \qquad Equation 8$$

The initial value βᵢₙᵢ may be set in various ways. For example, a value close to the actual value cannot be detected until the nonlinear coefficient \hat{β} is estimated, so that the initial value βᵢₙᵢ may be set to be [1 1]^{T} under an event in which a change in environmental factor is not significantly different for each scenario. For example, when a carrier frequency varies in a changed scenario but is not significantly different from a carrier frequency before the variation (for example, when a difference between the carrier frequency after the variation and the carrier frequency before the variation is within a threshold value), the initial value βᵢₙᵢ may be set to be [1 1]^{T}. However, such setting of the initial value βᵢₙᵢ is only an example and the initial value βᵢₙᵢ may be set to have various values for rapid estimation of the nonlinear coefficient satisfying Equation 3.

Alternatively, according to various example embodiments, the predistortion circuit 110 estimates a nonlinear coefficient significantly reducing the first error e_{m,1} through various optimization techniques such as Particle Swarm Optimization (PSO), Gradient Descent, or Newton.

The predistortion circuit 110 may estimate the first nonlinear coefficient β₁ and the second nonlinear coefficient β₂, significantly reducing the first error e_{m,1}, and may transmit the estimated first nonlinear coefficient β₁ to the second gain circuit 132 and transmit the second nonlinear coefficient β₂ to the first gain circuit 131.

In this case, the first gain circuit 131 may receive an input signal IN and may output an input signal IN, multiplied by the first gain, to the predistortion circuit 110. Even when a scenario is changed, the predistortion circuit 110 may output a predistortion signal PDS based on the reference predistortion information PDI rather than using changed predistortion information. Then, the second gain circuit 132 may output the predistortion signal PDS, output from the predistortion circuit 110, to the power amplifier 120 after multiplying the predistortion signal PDS by the second gain.

As described above, the RF circuit 101 may compensate for nonlinearity based on a change in scenario only by adjusting a gain of the gain circuits 131 and 132 with respect to the reference predistortion information PDI and the reference model 112 of the power amplifier 120. For example, the RF circuit 101 may effectively compensate for the nonlinearity by estimating a nonlinear coefficient, significantly reducing the first error e_{m,1} defined as a difference between the reference model 112 and the actual output signal OUT of the power amplifier 120, and using a reciprocal of the estimated nonlinear coefficient as the gain of the gain circuits 131 and 132. During the compensation of the nonlinearity, predistortion may be performed without deterioration of predistortion performance caused by a change in predistortion information PDI (for example, adjustment of information such as an order of predistortion or the number of delay taps). In addition, issues regarding a storage space and time required to extract information may be addressed by efficiently using the reference predistortion information PDI.

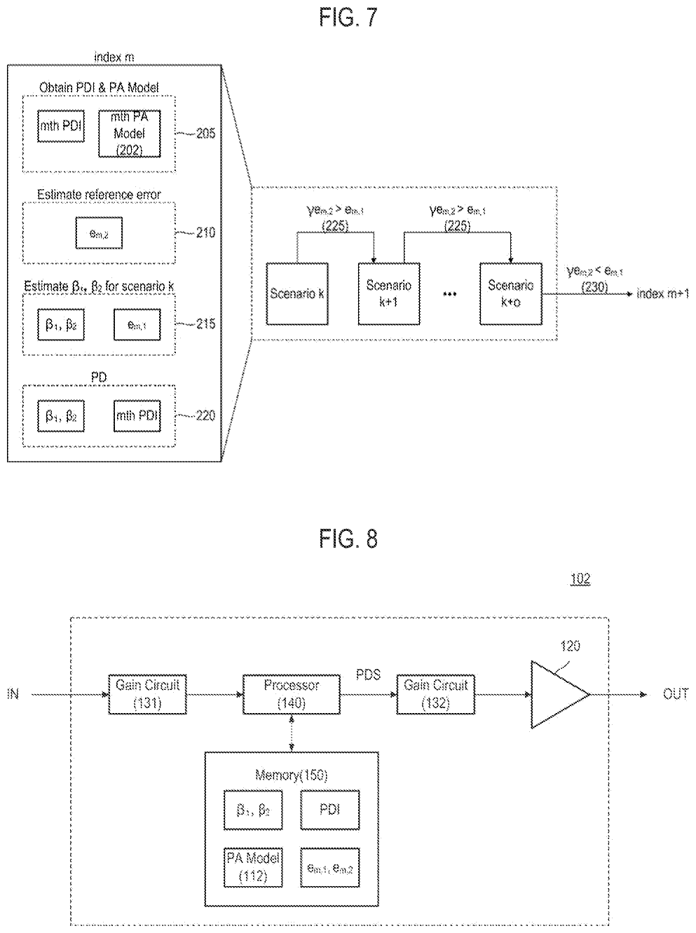

FIG. 7 is a diagram illustrating an operation of a predistortion circuit according to an example embodiment.

Referring to FIG. 7, the predistortion circuit 110 according to an example embodiment may operate in m-th reference predistortion information PDI and a k-th scenario (where m and k are positive integers). Here, m is an index of the reference predistortion information PDI, and a change in m may refer to a change in the reference predistortion information PDI. In addition, k is an index of a scenario, and a change in k may refer to a change in scenario (for example, environmental factors such as the above-mentioned carrier frequency, temperature, or magnitude of the output signal OUT).

The predistortion circuit 110 may set the index m of the reference predistortion information PDI and the index k of the scenario. For example, m and k may be set to zero as initial values.

The predistortion circuit 110 may obtain the m-th reference predistortion information PDI and an m-th reference model 112 of the power amplifier 120 (Operation 205).

The predistortion circuit 110 may estimate a second error e_{m,2} defined as a reference error (Operation 210). For example, the second error e_{m,2} may be defined as a difference a first output signal OUT, which is an actual output of the power amplifier 120 in a k-th scenario, and a third output signal which is an output of the reference model 112 obtained through Operation 205. For example, the second error e_{m,2} may be defined as ∥yₖ−f_{PA,k}(x)|₂², where yₖ may be the first output signal OUT, and f_{PA,k}(x) may be a third output signal. In this case, for indexing, an index of an m-th reference model 112 and an index of a model of a k-th power amplifier 120 may be set based on f_{PA,m}^{ref}(·)=f_{PA,k}(·) (where f_{PA,m}^{ref}(·) is the m-th reference model 112, and f_{PA,k}(·) is a model of the k-th power amplifier 120).

The predistortion circuit 110 may define the first error e_{m,1}, and may estimate a nonlinear coefficient at which the first error e_{m,1} is significantly reduced (Operation 215). For example, the first error e_{m,1} may be defined as Equation 1. The estimation of the nonlinear coefficient may be performed through various techniques, such as those described above.

The predistortion circuit 110 may perform predistortion using the estimated nonlinear coefficient and the m-th reference predistortion information PDI (Operation 220). For example, a reciprocal of the estimated nonlinear coefficient may be provided as a gain of an input/output terminal of the predistortion circuit 110, as described above.

According to Operations 205 to 220 described above, the predistortion circuit 110 may secure the reference predistortion information PDI and the reference model 112 for the index m, and may apply the reference predistortion information PDI and the reference model 112 to a k-th scenario to perform predistortion. When the k-th scenario is changed to a k+1-th scenario, the predistortion circuit 110 may perform an operation of comparing the second error e_{m,2}, weighted by an error weight γ, with the first error e_{m,1}. The error weight γ may be defined as, for example, a real number greater than 1.

For example, the predistortion circuit 110 may perform predistortion using reference predistortion information PDI of the same index m for a k+1-th scenario and the reference model 112, based on the first error e_{m,1} being smaller than the second error e_{m,2} weighted by the error weight γ (Operation 225). Because the scenario is changed, the nonlinear coefficient may be estimated for the k+1-th scenario. When satisfying the fact that the first error e_{m,1} is smaller than the second error e_{m,2} weighted by the error weight γ (Operation 225), the predistortion circuit 110 may perform predistortion using the reference predistortion information PDI of the same index m and the reference model 112 while continuing to change scenarios.

In a k+o-th scenario (where o is a positive integer), the predistortion circuit 110 may redefine the reference predistortion information PDI and the reference model 112, based on the first error e_{m,1} being greater than the second error e_{m,2} weighted by the error weight γ (Operation 230). For example, the predistortion circuit 110 may change the index m to m+1 and may newly perform Operations 205 to 220 on the changed index.

As described above, the RF circuit may perform predistortion by applying a single piece of reference predistortion information PDI and reference model 112 over several scenarios. For example, by identifying a maximum range of the scenarios in which multiple pieces of reference information, defined by comparing the second error e_{m,2}, weighted by the error weight γ, with the first error e_{m,1}, are available, the RF circuit may adaptively use the multiple pieces of reference information.

The description with respect to FIG. 7 is provided as an example, and example embodiments are not limited thereto. For example, the RF circuit may dynamically set the reference predistortion information PDI and/or the reference model 112 in consideration of scenarios and errors, as illustrated in FIG. 7. Alternatively, in some example embodiments, the reference predistortion information PDI and/or the reference model 112 may be preset for each scenario.

For example, when a plurality of operating frequency ranges of the RF circuit, for example, a plurality of subbands are present, the reference predistortion information PDI and/or the reference model 112 may be preset with respect to a center frequency of each of the plurality of subbands. In this case, the RF circuit may perform predistortion using reference predistortion information PDI and/or the reference model 112 preset based on an operating subband.

FIG. 8 is a diagram illustrating an RF circuit according to an example embodiment. Hereinafter, detailed descriptions of elements substantially the same as described above will be omitted.

Referring to FIG. 8, an RF circuit 102 according to an example embodiment may include a power amplifier 120, a first gain circuit 131 and a second gain circuit 132, a processor 140, and a memory 150.

The processor 140 may be connected between the first gain circuit 131 and the second gain circuit 132. For example, the processor 140 may be implemented as a general purpose processor, a specific purpose processor, or an application processor (AP). For example, the processor 140 may include an operation processor (for example, a central processing unit (CPU)) including a specific purpose logic circuit (for example, a field programmable gate array (FPGA), application specific integrated circuits (ASICs), or the like), a graphics processing unit (GPU), or the like, but example embodiments are not limited thereto.

The processor 140 may execute instructions and/or programs stored in the memory 150. Alternatively, the processor 140 may store data in the memory 150 or read stored data.

The processor 140 may control the overall operation of the RF circuit 102. The processor 140 may be configured to perform an operation of the predistortion circuit 110, as described above. For example, when the predistortion circuit 110 is implemented as software, instructions and/or programs stored in the memory 150 may be executed by the processor 140 to perform predistortion. However, it is understood that the predistortion circuit 110 may be implemented as hardware or as a combination of software and hardware, and may include firmware.

According to an example embodiment, the processor 140 may obtain reference predistortion information PDI and a reference model 112. The processor 140 may estimate a nonlinear coefficient based on significant reduction of the first error e_{m,1} defined based on the modeled reference model 112, the first output signal OUT, and the nonlinear coefficient. For example, the nonlinear coefficients may be estimated based on Equations 1 to 8, or may be estimated through other optimization techniques. The processor 140 may provide the estimated nonlinear coefficient to the gain circuits 131 and 132. For example, a first nonlinear coefficient β₁ may be provided to the second gain circuit 132 and the second nonlinear coefficient β₂ may be provided to the first gain circuit 131. The processor 140 may predistort an input signal IN based on the reference predistortion information PDI, and may output a predistortion signal PDS to the power amplifier 120.

As the predistortion is performed by the processor 140, the input signal IN may be applied to the processor 140 after being multiplied by the first gain through the first gain circuit 131 and the predistortion signal PDS may be applied to the power amplifier 120 after being multiplied by the second gain through the second gain circuit 132. Thus, the nonlinearity of the power amplifier 120 may be compensated for.

According to an example embodiment, the processor 140 may operate using m-th reference predistortion information PDI and a k-th scenario. The processor 140 may set m and k. The processor 140 may perform operations, on the set m and k, including acquisition of the reference predistortion information PDI and the reference model 112, estimation of the second error e_{m,2}, estimation of a nonlinear coefficient significantly reducing the first error e_{m,1}, and predistortion.

The processor 140 may determine a range of a scenario, in which the m-th reference predistortion information PDI and the reference model 112 are available, through an operation of comparing the second error e_{m,2}, weighted by an error weight γ, with a first error e_{m,1}. For example, when the first error e_{m,1} is smaller than the second error e_{m,2} weighted by the error weight γ, the processor 140 may perform estimation of the nonlinear coefficient and a predistortion operation while changing the scenario index k. For example, when the first error e_{m,1} is greater than the second error e_{m,2} weighted by the error weight γ, the processor 140 may change the index m.

The processor 140 may set the error weight γ. For example, the processor 140 may set the error weight γ to be relatively close to 1 to narrow a range in which the m-th reference predistortion information PDI and the reference model 112 are available, or may set the error weight γ to be far from 1 to expand the range in which the m-th reference predistortion information PDI and the reference model 112 are available. As the error weight γ is closer to 1, degradation of EVM and ACLR of the RF circuit 102 may be reduced. On the other hand, as the error weight γ is far from 1, the degradation of EVM and ACLR may be increased.

The processor 140 may store the acquired reference predistortion information PDI, reference model 112, nonlinear coefficient, first error e_{m,1}, and second error e_{m,2} or other parameters, acquired in relation to the predistortion operation, in the memory 150.

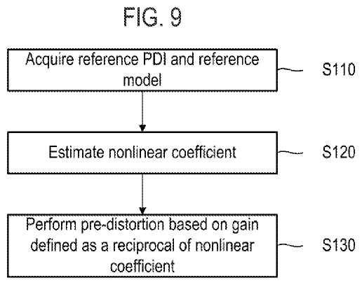

FIG. 9 is a flowchart illustrating a method of operating an RF circuit according to an example embodiment.

Referring to FIG. 9, in operation S110, the RF circuits 100 to 102 may acquire reference predistortion information PDI and a reference model 112.

In operation S120, the RF circuits 100 to 102 may estimate a nonlinear coefficient. For example, the RF circuits 100 to 102 may estimate a nonlinear coefficient by significantly reducing a first error e_{m,1} defined based on a first output signal OUT, output from the power amplifier 120, and a nonlinear coefficient. In operation S120, various optimization techniques for estimating a nonlinear coefficient may be applied.

In operation S130, the RF circuits 100 to 102 may perform predistortion based on a gain defined as a reciprocal of the nonlinear coefficient. The predistortion may be performed based on the reference predistortion information PDI. Operation S130 may further include an operation, in which a predistortion signal PDS is output by predistorting a signal obtained by multiplying an input signal IN by a first nonlinear coefficient Bi estimated in operation S120, and an operation in which a predistortion signal PDS multiplied by a reciprocal of a second nonlinear coefficient β₂ is output to the power amplifier 120.

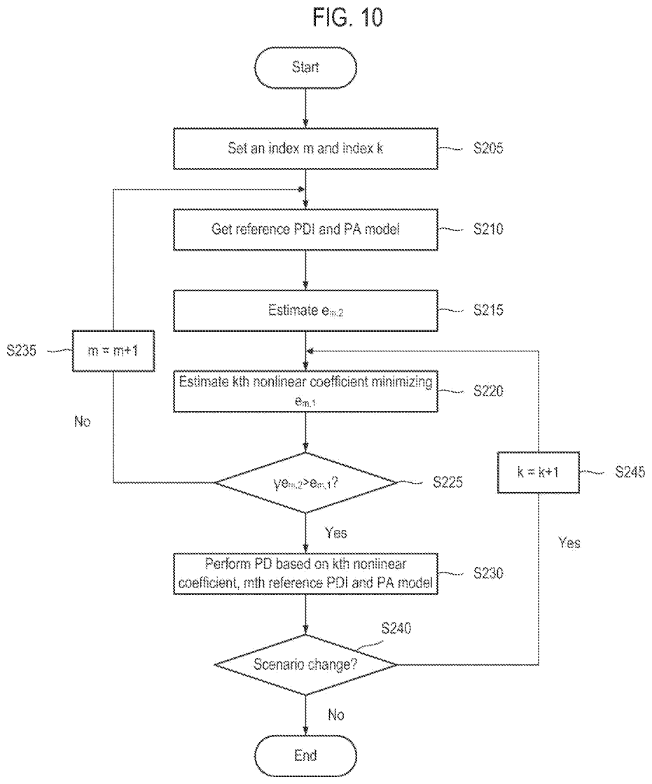

FIG. 10 is a flowchart illustrating a method of operating an RF circuit according to an example embodiment.

Referring to FIG. 10, in operation S205, the RF circuits 100 to 102 may set an index m of reference predistortion information PDI and a scenario index k. For example, initial values of the indices m and k may be set to 0. The indices m and k may have a maximum value M and a maximum value K (where M and K are positive integers), respectively. The maximum value K is the total number of scenarios of the RF circuits 100 to 102, and the maximum value M may refer to the number of multiple pieces of reference distortion information PDI that can be predistorted for K scenarios. For example, the maximum value M means that M pieces of reference predistortion information PDI may be used for K scenarios.

In operation S210, the RF circuits 100 to 102 may acquire m-th reference predistortion information PDI and an m-th reference model 112 for the index m.

In operation S215, the RF circuits 100 to 102 may estimate a second error e_{m,2} defined as a difference between a first output signal OUT and a third output signal that is an output of the reference model 112. For example, the second error e_{m,2} may be defined as ∥yₖ−f_{PA,k}(x)∥₂².In addition, the RF circuits 100 to 102 may set an index of the m-th reference model 112 and an index of a model of the k-th power amplifier 120 to be the same for indexing.

In operation S220, the RF circuits 100 to 102 may estimate a k-th nonlinear coefficient at which a first error e_{m,1}, defined based on the m-th reference model 112, the first output signal OUT, and the nonlinear coefficient, is significantly reduced. The RF circuits 100 to 102 may perform an operation of loading the m-th reference model 112 from the above-described memory 150 to estimate the nonlinear coefficient.

In operation S225, the RF circuits 100 to 102 may compare the second error e_{m,2}, weighted by an error weight γ, with the first error e_{m,1}. The error weight γ may be defined as, for example, a real number greater than 1 and may be preset or set by the predistortion circuit 110 (or the processor 140).

In operation S225, when the first error e_{m,1} is smaller than the second error e_{m,2} weighted by the error weight γ, the flow proceeds to operation S230 in which the RF circuits 100 to 102 may perform predistortion based on the k-th nonlinear coefficients, the m-th reference predistortion information PDI, and the reference model 112. For example, the RF circuits 100 to 102 may predistort an input signal IN based on a gain defined as a reciprocal of the m-th reference predistortion information PDI and the k-th nonlinear coefficient.

Alternatively, in operation S225, when the first error e_{m,1} is greater than the second error e_{m,2} weighted by the error weight γ, the flow proceeds to operation 235 in which the RF circuits 100 to 102 may increase the index m by 1. Then, the RF circuits 100 to 102 may redefine the reference predistortion information PDI and the reference model 112 for the new index m. For example, the RF circuits 100 to 102 may perform operations S210 to S225 on the new index m.

In operation S240 following operation S230, the RF circuits 100 to 102 may determine whether a scenario is changed. If the scenario is not changed, then the flow may end.

Alternatively, when the scenario is changed, the flow proceeds to operation S245 in which the RF circuits 100 to 102 may increase the scenario index k by 1. Then, the RF circuits 100 to 102 may reestimate a nonlinear coefficient for the new index k. For example, the RF circuits 100 to 102 may perform operations S220 to S240 for the new index k. In this case, the first error e_{m,1} for estimating a nonlinear coefficient may be defined based on a first output signal OUT that is an actual output of a new k-th power amplifier 120, the m-th reference model 112, and the new k-th nonlinear coefficient.

When the RF circuits 100 to 102 perform operation S225 based on the nonlinear coefficient estimated for the new k, and the first error e_{m,1} is then determined to be greater than the second error e_{m,2} weighted by the error weight γ, the RF circuits 100 to 102 may determine that existing reference predistortion information PDI can be no longer used in a corresponding scenario (for example, a scenario corresponding to the new index k) and may change the index m.

The description with respect to FIG. 10 is provided as an example, and example embodiments are not limited thereto. As described above, the reference predistortion information PDI and/or the reference model 112 may be preset for each scenario.

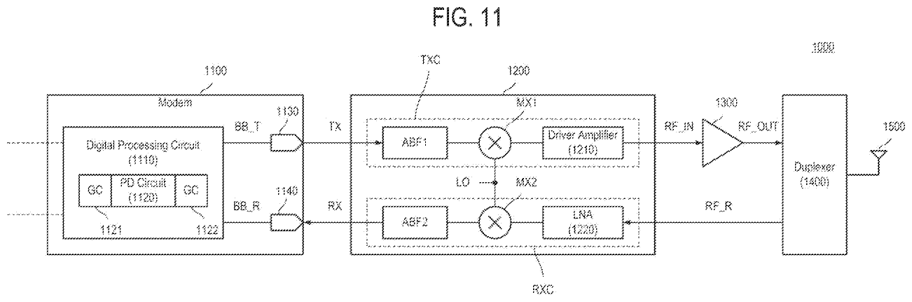

FIG. 11 is a diagram illustrating a wireless communication device according to an example embodiment.

Referring to FIG. 11, a wireless communication device 1000 according to an example embodiment may include a modem 1100, a radio-frequency integrated circuit (RFIC) 1200, a power amplifier 1300, a duplexer 1400, and an antenna 1500.

The modem 1100 may include a digital processing circuit 1110, an analog-to-digital converter (ADC) 1130, and a digital-to-analog converter (DAC) 1140. The modem 1100 may process a baseband signal BB_T (including, for example, an I signal and a Q signal) including information to be transmitted through the digital processing circuit 1110 based on various communication methods. The modem 1100 may process the received baseband signal BB_R through the digital processing circuit 1110 according to various communication methods.

For example, the modem 1100 may process a signal to be transmitted or a received signal, according to various communication methods such as orthogonal frequency division multiplexing (OFDM), orthogonal frequency division multiple access (OFDMA), wideband code multiple access (WCDMA), or high speed packet access+ (HSPA+). In addition, the modem 1100 may process a baseband signal BB_T or BB_R according to various communication methods (for example, various communication methods to which a technique for modulating or demodulating an amplitude and a frequency of the baseband signal BB_T or BB_R is applied).

The digital processing circuit 1110 may perform various processing operations on the baseband signal in a digital domain. The digital processing circuit 1110 may perform a predistortion operation, as described above. The digital processing circuit 1110 may include a predistortion circuit 1120 and gain circuits 1121 and 1122 to perform the predistortion operation.

The predistortion circuit 1120 may perform a predistortion operation, as described above. For example, the predistortion circuit 1120 may be configured to predistort the baseband signal BB_T based on reference predistortion information PDI. The gain circuits 1121 and 1122 may be provided on input/output terminals of the predistortion circuit 1120. The gain circuits 1121 and 1122 may be configured to provide gains, each defined as a reciprocal of a nonlinear coefficient for the power amplifier 1300, to the input/output terminals of the predistortion circuit 1120. For example, the first gain circuit 1121 may be configured to provide a first gain, defined as a reciprocal of a second nonlinear coefficient β₂ for the output terminal of the power amplifier 1300, to the input terminal of the predistortion circuit 1120. For example, the second gain circuit 1122 be configured to provide a second gain, defined as a reciprocal of a first nonlinear coefficient β₁ for the input terminal of the power amplifier 1300, to the output terminal of the predistortion circuit 1120.

The baseband signal BB_T may be predistorted through the predistortion circuit 1120 to compensate for nonlinearity of the power amplifier 1300. For example, the nonlinearity of the power amplifier 1300 in a changed scenario may be compensated for through the gain circuits 1121 and 1122 according to example embodiments.

At least one of the ADC 1140 and the DAC 1130 may be provided. The modem 1100 may convert the baseband signal BB_T into analog using the DAC 1130 to generate a transmit signal TX. Also, the modem 1100 may receive a receive signal RX, an analog signal, from the RFIC 1200. Also, the modem 1100 may digitally convert the received signal RX through the ADC 1140, provided therein, to extract the baseband signal BB_R as a digital signal. For example, the receive signal RX may be a differential signal including a positive signal and a negative signal.

The RFIC 1200 may perform frequency up-conversion on the transmit signal TX to generate an RF input signal RF_IN, or may perform frequency down-conversion on an RF receive signal RF_R to generate a receive signal RX. For example, the RFIC 1200 may include a transmit circuit TXC for frequency up-conversion, a receive circuit RXC for frequency down-conversion, and a local oscillator LO.

The transmit circuit TXC may include a first analog baseband filter ABF1, a first mixer MX1, and a driver amplifier 1210. For example, the first analog baseband filter ABF1 may include a low pass filter.

The baseband filter ABF1 may filter the transmit signal TX received from the modem 1100 and provide the filtered transmit signal TX to the first mixer MX1. The first mixer MX1 may perform frequency up-conversion to convert a frequency of the transmit signal TX from a baseband to a high-frequency band using a frequency signal provided by the local oscillator LO. The frequency up-conversion may allow the transmit signal TX to be provided to the driver amplifier 1210 as the RF input signal RF_IN. The driver amplifier 1210 may primarily power-amplify the RF input signal RF_IN and provide the power-amplified RF input signal to the power amplifier 1300.

The power amplifier 1300 may receive a DC voltage or a variable power supply voltage (for example, a dynamically variable output voltage), and may secondarily amplify power of the RF input signal RF_IN based on the supplied power supply voltage to generate an RF output signal RF_OUT. The power amplifier 1300 may provide the generated RF output signal RF_OUT to the duplexer 1400.

The receive circuit RXC may include a second analog baseband filter ABF2, a second mixer MX2, and a low-noise amplifier (LNA) 1220. For example, the second analog baseband filter ABF2 may include a low pass filter.

The LNA 1220 may amplify the RF receive signal RF_R received from the duplexer 1400 and provide the amplified RF receive signal RF_R to the second mixer MX2. The second mixer MX2 may perform frequency down-conversion to convert a frequency of the receive signal RF_R from a high-frequency band to a baseband using the frequency signal provided by the local oscillator LO. The frequency down-conversion may allow the RF receive signal RF_R to be provided to the second analog baseband filter ABF2 as the received signal RX. The second analog baseband filter ABF2 may filter the receive signal RX and provide the filtered receive signal RX to the modem 1100.

For reference, the wireless communication device 1000 may transmit a transmit signal through a plurality of frequency bands using carrier aggregation (CA). To this end, the wireless communication device 1000 may include a plurality of power amplifiers 1300, each of which is configured to power-amplify an RF input signal RF_IN corresponding to a carrier. For ease of description, an example will be provided where a single power amplifier 1300 is provided.

The duplexer 1400 may be connected to an antenna 1500 to separate a transmit frequency and a receive frequency. For example, the duplexer 1400 may separate the RF output signal RF_OUT, provided from the power amplifier 1300, for each frequency band and provide the separated RF output signal RF_OUT to a corresponding antenna 1500. Also, the duplexer 1400 may provide an external signal, received from the antenna 1500, to the LNA 1220 of the receive circuit RXC of the RFIC 1200. For example, the duplexer 1400 may include a front end module with integrated duplexer (FEMiD).

For reference, the wireless communication device 1000 may be provided with a switch structure for separating a transmit frequency and a receive frequency, rather than the duplexer 1400. Also, the wireless communication device 1000 may be provided with a structure including a duplexer 1400 and a switch to separate a transmit frequency from a receive frequency. For ease of description, an example will be provided where the wireless communication device 1000 is provided with a duplexer 1400 for separating a transmit frequency and a receive frequency.

The antenna 1500 may transmit an RF output signal RF_OUT, frequency-separated by the duplexer 1400, to an external entity or may provide an RF receive signal RF_R, received from an external entity, to the duplexer 1400. For example, the antenna 1500 may include an array antenna, but example embodiments are not limited thereto.

For reference, each of the modem 1100, the RFIC 1200, the power amplifier 1300, and the duplexer 1400 may be implemented as an IC, a chip, or a module. In addition, the modem 1100, the RFIC 1200, the power amplifier 1300, and the duplexer 1400 may be mounted together on a printed circuit board (PCB). However, example embodiments are not limited thereto. In some example embodiments, at least a portion of the modem 1100, the RFIC 1200, the power amplifier 1300, and the duplexer 1400 may be implemented as a single communication chip.

Furthermore, the wireless communication device 1000 illustrated in FIG. 11 may be included in a wireless communication system using a cellular network such as 5G or LTE, or may be included in a wireless local area network (WLAN) system or any other wireless communication system. For reference, the configuration of the wireless communication device 1000 illustrated in FIG. 11 is only an example, and example embodiment are not limited thereto. The wireless communication device 100 illustrated in FIG. 11 may be configured in various ways based on communication protocols or communication schemes.

As set forth above, according to example embodiments, a radio-frequency (RF) circuit, supporting predistortion to compensate for nonlinear variation caused by a change in environment, and a method of operating the same may be provided.

While aspects of example embodiments have been shown and described above, it will be apparent to those skilled in the art that modifications and variations could be made without departing from the scope of the appended claims.

What is claimed is:

1. A radio-frequency (RF) circuit comprising:
a power amplifier;
a predistortion circuit configured to predistort an input signal based on reference predistortion information to obtain a predistortion signal, and output the predistortion signal to the power amplifier; and
a gain circuit configured to provide a gain, corresponding to a reciprocal of a nonlinear coefficient of the power amplifier, to the predistortion circuit.

2. The RF circuit of claim 1, wherein the nonlinear coefficient comprises a first nonlinear coefficient corresponding to an input terminal of the power amplifier, and a second nonlinear coefficient corresponding to an output terminal of the power amplifier.

3. The RF circuit of claim 2, wherein the gain circuit comprises:
a first gain circuit configured to provide a first gain, corresponding to a reciprocal of the second nonlinear coefficient, to an input terminal of the predistortion circuit; and
a second gain circuit configured to provide a second gain, corresponding to a reciprocal of the first nonlinear coefficient, to an output terminal of the predistortion circuit.

4. The RF circuit of claim 3, wherein the first gain circuit is configured to output the input signal, multiplied by the first gain, to the predistortion circuit, and
wherein the second gain circuit is configured to output the predistortion signal, multiplied by the second gain, to the power amplifier.

5. The RF circuit of claim 2, wherein the predistortion circuit is configured to estimate the nonlinear coefficient based on reduction of a first error defined based on a reference model corresponding to the power amplifier, a first output signal output from the power amplifier, and the nonlinear coefficient.

6. The RF circuit of claim 5, wherein the first error is a normalized mean square error (NMSE) between a second output signal and the first output signal, and
wherein the second output signal is output while the first nonlinear coefficient and the second nonlinear coefficient are applied to the reference model.

7. The RF circuit of claim 6, wherein the predistortion circuit is configured to estimate a second error based on a difference between the first output signal and a third output signal, and
wherein the third output signal is an output of the reference model.

8. The RF circuit of claim 7, wherein the predistortion circuit is configured to predistort the input signal based on the first error being smaller than the second error weighted by an error weight.

9. The RF circuit of claim 7, wherein the predistortion circuit is configured to redefine the reference predistortion information and the reference model based on the first error being greater than the second error weighted by an error weight.

10. A method of operating a radio-frequency (RF) circuit, the method comprising:
setting an index m of reference predistortion information, wherein m is a positive integer;
obtaining m-th reference predistortion information and an m-th reference model corresponding to the index m as a reference model, the reference model corresponding to a power amplifier;
identifying a gain corresponding to a reciprocal a nonlinear coefficient for the m-th reference predistortion information and the power amplifier; and
predistorting an input signal based on the gain.

11. The method of claim 10, wherein the nonlinear coefficient comprises a first nonlinear coefficient, corresponding to an input terminal of the power amplifier, and a second nonlinear coefficient corresponding to an output terminal of the power amplifier.

12. The method of claim 11, further comprising:
predistorting a signal, obtained by multiplying the input signal by the first nonlinear coefficient, to obtain a predistortion signal; and
outputting the predistortion signal, multiplied by a reciprocal of the second nonlinear coefficient, to the power amplifier.

13. The method of claim 10, further comprising estimating the nonlinear coefficient based on reduction of a first error defined based on a first output signal, output from the power amplifier, and the nonlinear coefficient.

14. The method of claim 13, further comprising:
estimating a second error based on a difference between the first output signal and a third output signal, the third output signal being an output of the reference model; and
comparing the second error, weighted by an error weight, with the first error.

15. The method of claim 14, further comprising:
performing the predistortion based on the first error being smaller than the second error weighted by the error weight; and
redefining the reference predistortion information and the reference model based on the first error being greater than the second error weighted by the error weight.

16. The method of claim 15, further comprising adjusting the index m based on the first error being greater than the second error weighted by the error weight.

17. A wireless communication device comprising:
a modem configured to process a baseband signal;
a radio-frequency integrated circuit (RFIC) configured to convert the baseband signal into a radio-frequency (RF) signal;
a power amplifier configured to amplify the RF signal; and
an antenna configured to transmit and receive the RF signal,
wherein the modem comprises:
a predistortion circuit configured to predistort the baseband signal based on predistortion information; and
a gain circuit configured to provide a gain, corresponding to a reciprocal of a nonlinear coefficient of the power amplifier, to the predistortion circuit.

18. The wireless communication device of claim 17, wherein the nonlinear coefficient comprises a first nonlinear coefficient, corresponding to an input terminal of the power amplifier, and a second nonlinear coefficient corresponding to an output terminal of the power amplifier, and
wherein the gain circuit comprises:
a first gain circuit configured to provide a first gain, corresponding to a reciprocal of the second nonlinear coefficient, to an input terminal of the predistortion circuit; and
a second gain circuit configured to provide a second gain, corresponding to a reciprocal of the first nonlinear coefficient, to the predistortion circuit.

19. The wireless communication device of claim 17, wherein the predistortion circuit is configured to estimate the nonlinear coefficient based on reduction of a first error defined based on a reference model corresponding to the power amplifier, a first output signal output from the power amplifier, and the nonlinear coefficient.

20. The wireless communication device of claim 19, wherein the nonlinear coefficient comprises a first nonlinear coefficient, corresponding to an input terminal of the power amplifier, and a second nonlinear coefficient corresponding to an output terminal of the power amplifier,
wherein the first error is a normalized mean square error (NMSE) between a second output signal and the first output signal, and
wherein the second output signal is output while the first nonlinear coefficient and the second nonlinear coefficient are applied to the reference model.
